(19) United States
(12) Patent Application Publication
(10) Pub. No.: US 2013/0335075 A1
(43) Pub. Date: Dec. 19, 2013

(54) SEAL SYSTEM AND METHOD FOR SYSTEM PROBE

(71) Applicants: Michael Scott Davis, Washoe Valley, NV (US); Alex James Kuhlmann, Minden, NV (US)

(72) Inventors: Michael Scott Davis, Washoe Valley, NV (US); Alex James Kuhlmann, Minden, NV (US)

(73) Assignee: General Electric Company, Schenectady, NY (US)

(21) Appl. No.: 13/523,864

(22) Filed: Jun. 14, 2012

(51) Int. Cl. G01R 33/12; B23P 17/04

(52) U.S. Cl. 324/239; 29/557

(57) ABSTRACT

A system includes a probe assembly having sensing circuitry configured to sense at least one parameter relating to a rotating machine and a cable coupled to the sensing circuitry. The probe assembly also includes a molded probe body that is integrally molded about the cable and the sensing circuitry and a machined groove disposed on the molded probe body. The machined groove includes a machined surface.

### BACKGROUND OF THE INVENTION

The subject matter disclosed herein relates to sensor probes, such as sensor probes used in various rotating machines, including turbomachines.

Turbomachines include compressors and turbines, such as gas turbines, steam turbines, and hydro turbines. Generally, turbomachines include blades coupled to a rotor, which may include a shaft, drum, disk, or wheel. Turbomachines may operate with high internal temperatures and high internal pressures relative to the external environment. Turbomachines may include monitoring systems, which include sensor probes, to monitor degradation of the rotating parts. The sensor probes may extend through part of the turbomachine from the external environment to the internal environment. The internal environment may have fluids, such as combustion gases, at high internal temperatures and high internal pressures. Unfortunately, fluids from the internal environment at high internal pressures may potentially leak around an inserted sensor probe due to various surface imperfections or roughness.

### BRIEF DESCRIPTION OF THE INVENTION

Certain embodiments commensurate in scope with the originally claimed invention are summarized below. These embodiments are not intended to limit the scope of the claimed invention, but rather these embodiments are intended only to provide a brief summary of possible forms of the invention. Indeed, the invention may encompass a variety of forms that may be similar to or different from the embodiments set forth below.

In a first embodiment, a system a probe assembly having sensing circuitry configured to sense at least one parameter relating to a rotating machine and a cable coupled to the sensing circuitry. The probe assembly also includes a molded probe body that is integrally molded about the cable and the sensing circuitry and a machined groove disposed on the molded probe body. The machined groove includes a machined surface.

In a second embodiment, a system includes a proximity probe having sensing circuitry, a molded probe body, and a machined groove disposed on the molded probe body. The sensing circuitry is configured to sense at least one parameter relating to a turbomachine blade. The molded probe body is integrally molded about the sensing circuitry and has an exterior with a first surface finish. The machined groove includes a machined surface with a second surface finish that is smoother than the first surface finish.

In a third embodiment, a method includes machining a groove in a probe body of a proximity probe after the probe body is integrally molded about sensing circuitry configured to sense at least one parameter relating to a turbomachine. Machining the groove creates a machined surface in the groove configured to support a gasket.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a schematic of an embodiment of a gas turbine engine having a turbomachine monitoring system with one or more sensor probes;

FIG. 2 is a schematic of an embodiment of a turbomachine monitoring system of FIG. 1, illustrating a sensor probe in a turbine section taken along line 2-2 of FIG. 1;

FIG. 3 is a cross-sectional side view of an embodiment of a turbomachine probe assembly with a probe body integrally molded about sensing circuitry;

FIG. 4 is a cross-sectional end view of an embodiment of the turbomachine probe assembly of FIG. 3 taken within line 4-4;

FIG. 5 is a cross-sectional side view of an embodiment of the turbomachine probe assembly of FIGS. 3 and 4, illustrating a machined groove formed after integrally molding the probe body about the sensing circuitry;

FIG. 6 is a cross-sectional end view of an embodiment of the turbomachine probe assembly of FIG. 5 taken within line 5-5;

FIG. 7 is a cross-sectional side view of an embodiment of the turbomachine probe assembly of FIGS. 5 and 6, further illustrating a gasket disposed in the machined groove; and

FIG. 8 is a cross-sectional view of an embodiment of the turbomachine probe assembly of FIGS. 6 and 7 mounted within a casing.

### DETAILED DESCRIPTION OF THE INVENTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements. The term “roughness” is a measure of surface finish and is intended to refer to a measure of the texture of a surface. Roughness may be quantified by the relative vertical or radial deviations of the surface measured in micrometers (μm) or microinches (μ-in).

The disclosed embodiments relate to probe assemblies for rotating machinery (e.g., turbomachinery), which are manufactured from the inside out by molding a body integrally around sensing circuitry, rather than manufacturing from the outside in by first producing the body and then subsequently installing the sensing circuitry into the body. The disclosed embodiments are particularly advantageous as the sensing circuitry may be substantially or completely encapsulated within the molded body, such that the exterior of the sensing circuitry is continuously fixedly adhered to and sealed with the interior of the molded body. Thus, the molded in place construction of the seal assembly may provide substantially continuous structural support of the sensing circuitry, while also blocking leakage of fluids (e.g., liquid or gas) between the sensing circuitry and the molded body without any intermediate seal (e.g., O-ring seal). As discussed below, the disclosed embodiments include a manufacturing process of placing sensing circuitry into a mold, injecting a mold material into the mold to form the body integrally about the sensing circuitry, and subsequently machining one or more seal grooves to ensure a smooth sealing surface for seals (e.g., O-ring seals). The seal grooves may be initially formed as molded seal grooves as part of the molding process, yet the surface finish of the molded seal grooves may form an insufficient seal between the probe assembly and the probe aperture. Thus, while the sensing circuitry is already molded integrally within the body, the disclosed embodiments may refine the surface of the molded groove by machining the groove. However, the seal grooves also may be machined into the molded body without previously molded seal grooves. In either case, each seal groove (whether initially molded in the body or not) may be machined to produce a machined groove with a substantially smooth surface, thereby improving the effectiveness of a seal or gasket disposed within the groove.

As discussed below, embodiments of the present disclosure are directed toward a probe assembly configured to monitor one or more interior portions of a rotating machine, including axles, wheels, pulleys, conveyors, gears, cams, and other rotating equipment. Some embodiments are directed toward a turbomachine probe assembly configured to monitor one or more interior portions of a turbomachine, such as blades of a compressor, turbine, or other turbomachine. For example, the probe assembly may be disposed within a casing of the turbomachine to monitor the internal environment of the turbomachine, e.g., temperature, pressure, combustion dynamics, vibration, defects or cracks, speed, flow rate, clearance, exhaust emissions, and so forth. Again, the probe assembly may include a molded probe body integrally molded about sensing circuitry (e.g., inductive coil), a cable electrically coupled to the sensing circuitry, a gasket or seal, and a fitting. Some embodiments of the probe assembly may also include a shroud about a probe tip of the probe assembly. Some embodiments may include a sheath disposed about the fitting where the sheath is configured to mount the probe assembly within the casing of the turbomachine. Again, the molded probe body may initially include at least one molded groove configured to receive a gasket to seal with the fitting, wherein the at least one molded groove and the outer surface may have a first surface finish. Each of the at least one molded grooves may be machined to form a machined groove (e.g., base and sides) having a second surface finish with a lower roughness than the first surface finish. The machined groove may be configured to receive the gasket and form a first seal with the fitting. The machined groove and gasket may be configured to seal with the fitting up to fluid pressures from 0.69 MPa (100 psi) to approximately 15.51 MPa (2250 psi). The machined groove may be substantially symmetrical about an axis of the probe assembly, uniform in depth and width, and conform to specifications for the gasket. The machined groove may provide consistent and increased seal quality among molded probes. The machined groove may also decrease manufacturing costs to produce probe assemblies capable of forming seals at high pressures and decrease maintenance costs due to replacement of probe assemblies.

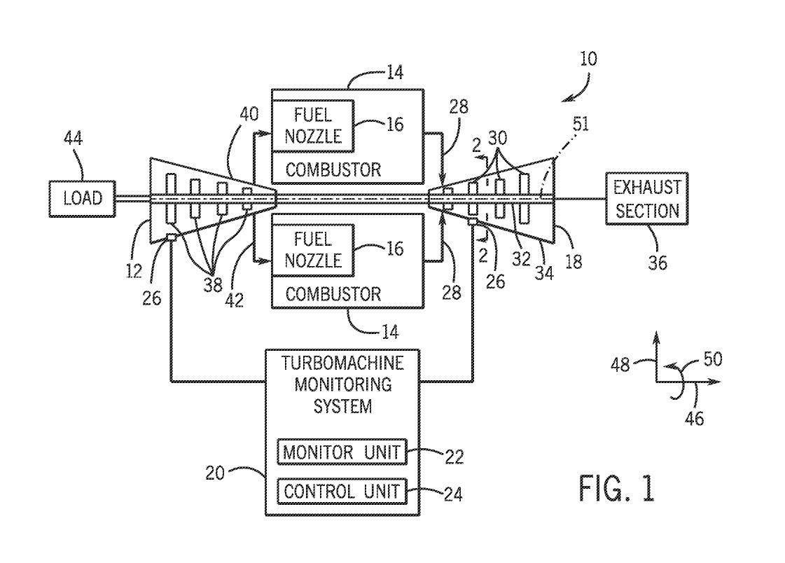

FIG. 1 illustrates a block diagram of an embodiment of a gas turbine system 10 having a compressor section 12 (e.g., a compressor) and a turbine section 18 (e.g., a turbine) with a turbomachine monitoring system 20 (e.g., including a monitor unit 22, a control unit 24, and a turbomachine probe assembly 26). The turbomachine monitoring system 20 may be configured to monitor blades (e.g., turbine blades 30, compressor blades 38) or other rotating components within a turbomachine. The turbomachine probe assembly 26 may include a molded probe body molded about sensing circuitry. As discussed in detail below, the molded probe body of the turbomachine probe assembly 26 may have a machined groove to form a seal within the probe assembly 26. The system 10 also includes combustors 14 having fuel nozzles 16. The fuel nozzles 16 route a liquid fuel and/or gas fuel, such as natural gas or syngas, into the combustors 14. The combustors 14 ignite and combust a fuel-air mixture that may be mixed within the combustor 14, and then pass hot pressurized combustion gases 28 (e.g., exhaust) into the turbine section 18.

Turbine blades 30 are coupled to a rotor 32 (e.g., shaft, wheel), which is also coupled to several other components throughout the turbine system 10, as illustrated. The turbine section 18 also includes a turbine casing 34, which supports turbomachine probe assemblies 26 (e.g., eddy current proximity probes, microwave proximity probes, temperature probes, clearance probes) of the turbomachine monitoring system 20, as described in further detail below. The turbomachine monitoring system 20 may be used to monitor the health or operation of the turbine blades 30. As the combustion gases 28 pass through the turbine blades 30 in the turbine section 18, the turbine section 18 is driven into rotation, which causes the rotor 24 to rotate. Eventually, the combustion gases 28 exit the turbine section 18 via an exhaust outlet 36.

The compressor section 12 includes compressor blades 38 surrounded by a compressor casing 40. The blades 38 within the compressor section 12 are coupled to the rotor 32, and rotate as the rotor 32 is driven into rotation by the turbine section 18, as discussed above. The turbomachine monitoring system 20 may further be used to monitor the health or operation of the compressor blades 38. As the blades 38 rotate within the compressor section 12, the blades 38 compress air from an air intake into pressurized air 42, which may be routed to the combustors 14, the fuel nozzles 16, and other portions of the gas turbine system 10.

The fuel nozzles 14 may then mix the pressurized air 42 and fuel to produce a suitable fuel-air mixture, which combusts in the combustors 14 to generate the combustion gases 28 to drive the turbine section 18. Further, the rotor 32 may be coupled to a load 44, which may be powered via rotation of the rotor 32. By way of example, the load 44 may be any suitable device that may generate power via the rotational output of the turbine system 10, such as a power generation plant or an external mechanical load. For instance, the load 44 may include an electrical generator, a fan of an aircraft engine, and so forth. In the following discussion, reference may be made to an axial direction 46, a radial direction 48, and a circumferential direction 50 relative to a rotational axis 51.

The turbomachine monitoring system 20 includes the monitor unit 22 and the control unit 24. The turbomachine monitoring system 20 (e.g., the monitor unit 22) may monitor the health of the turbine blades 30 and/or the compressor blades 38 of the gas turbine system 10 with a turbomachine monitoring assembly 26 that is a blade monitoring probe assembly. For example, monitoring blade health may include monitoring cracks, defects, vibrations, speeds, temperature, clearance, or other characteristics of the gas turbine system, such as the turbine blades 30 and/or compressor blades 38. The turbomachine probe assembly 26 may be disposed in the turbine combustor, the fuel nozzle, or any stationary or movable portion of the gas turbine system 10. As will be appreciated, the blade characteristics monitored by the turbomachine monitoring system 20 configured to monitor the turbine 18 or compressor 12 may vary depending on the type of blade being monitored (e.g., turbine blades 30 or compressor blades 38). Additionally, the turbomachine monitoring system 20 (e.g., the monitor unit 22) may monitor a clearance between the turbine blades 30 and the turbine casing 34 and/or a clearance between the compressor blades 38 and the compressor casing 40. Furthermore, the turbomachine monitoring system 20 (e.g., the control unit 24) may regulate, modify, or control the operation of the gas turbine system 10 (e.g., the compressor section 12 and/or the turbine section 18) based on the data monitored by the turbomachine monitoring system 20 (e.g., the monitor unit 22). While the embodiments of the turbomachine monitoring system 20 discussed below are described in the context of the turbine section 18, it is important to note that the turbomachine monitoring system 20 may be used with the compressor section 12 or other turbomachine. For example, the turbomachine monitoring system 20 may be used with a standalone compressor, steam turbine, hydro turbine, or other rotating machine.

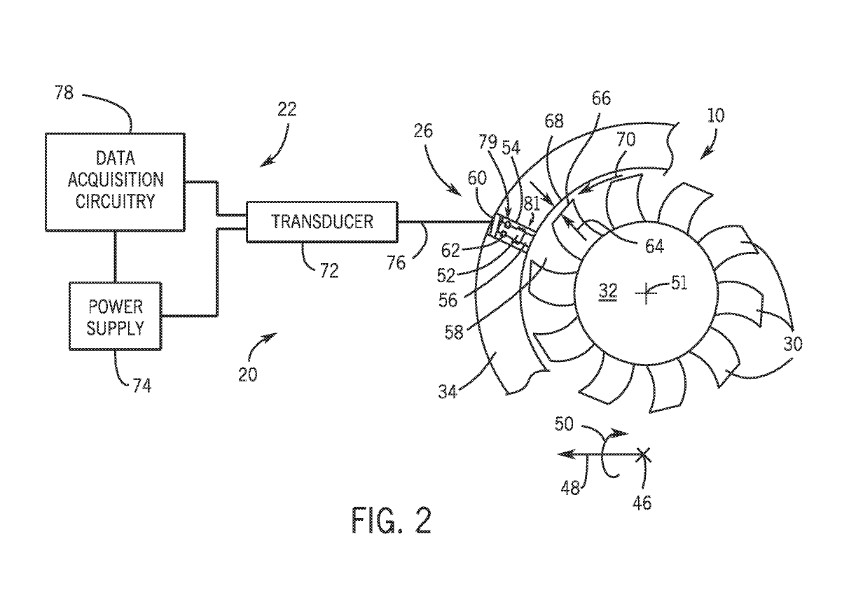

FIG. 2 is a schematic illustrating an embodiment of a turbomachine monitoring system 20 (e.g., the monitor unit 22), which may be used with the compressor section 12 and the turbine section 18 or other turbomachines. The turbomachine probe assembly 26 in the illustrated embodiment includes a probe 52 (e.g., eddy current proximity probe) disposed within the turbine casing 34 surrounding the turbine blades 30 and the rotor 32. As discussed in detail below, the probe 52 may be integrally molded with sensing circuitry and have at least one machined groove to seal with the turbine casing 34 or other structure in which the probe 52 is disposed. Specifically, the probe 52 of FIG. 2 is disposed in an aperture 54 of the turbine casing 34, which extends entirely through the turbine casing 34 in the radial direction 48. In this manner, a probe tip 56 of the probe 52 faces an interior 58 of the turbine section 18. The probe 52 may be disposed at least partially within a fitting 60 configured to mount the turbomachine probe assembly 26 in the aperture 54 of the turbine casing 34. Only a portion of the fitting 60 is shown in FIG. 2 for clarity of the probe 52 and probe tip 56. As discussed in detail below, the turbomachine probe assembly 26 may have one or more gaskets 62 (e.g., 0-ring seals) disposed about the probe 52 and configured to seal the probe 52 and fitting 60 to retain combustion gases 28 in the interior 58. In certain embodiments, the probe 52 may be an eddy current probe or a microwave proximity probe having a shroud around the probe tip 56, as described below. The probe 52 may also be a temperature probe such as a thermocouple or a thermistor. In some embodiments, the probe 52 of the turbomachine monitoring system 20 may include, but is not limited to, an emissions sensor probe, a flame sensor probe, a combustion dynamics sensor probe, a pressure sensor probe, a temperature sensor probe, or a flow rate sensor probe. While the embodiments of the probe 52 discussed below are described in the context of the proximity probes configured to sense conditions relating to the health of turbine blades 30 and/or compressor blades 38, it is important to note that the probe 52 may configured to sense other conditions within the gas turbine system 10. As will be appreciated, eddy current probes may not be susceptible to magnetic fields and may not induce magnetic fields significant enough to affect the blades 30 of the turbine section 18 or other electronics of the turbine section 18 or the gas turbine system 10.

The probe 52 may be configured to measure a clearance 64 (e.g., a radial 48 distance relative to the probe 52) between an outer radial edge 66 of the turbine blade 30 and an inner wall 68 of the casing 34. For example, changes in the impedance of a wire coil of an eddy current probe 52 may indicate a change in the clearance 64 between the outer radial edge 66 of the turbine blade 30 and the inner wall 68 of the casing 34. In certain embodiments, the impedance change of the wire coil of the eddy current probe 52 may be converted to a voltage output (e.g., by the monitor unit 22), which may change in amplitude in response to a change in the clearance 64. While the illustrated embodiment shows one turbomachine probe assembly 26, the turbomachine monitoring system 20 may include multiple turbomachine probe assemblies 26 disposed within the turbine casing 34 of the turbine section 18. As discussed in detail below, the turbomachine probe assembly 26 may include sheaths, shrouds, or other components to fit the probe 52 into existing apertures 54 of the turbine casing 34, as well as improve the life and operation of the probe 52.

In operation, the probe 52 (e.g., eddy current probe) is configured to detect the time of arrival and the time of departure of each of the turbine blades 22 as the turbine blades 22 rotate in a circumferential direction 70 within the turbine casing 34. For example, the probe 52 may be configured to induce eddy currents to detect the arrival and departure of each turbine blade 30 as each blade 30 passes the probe tip 56 of the probe 52. More specifically, a transducer 72 powered by a power supply 74 of the turbomachine monitoring system 20 drives the probe 52 by providing a driving signal to the probe 52 along a probe cable 76. The probe 52 sends a return signal to the transducer 72 along the cable 76. The probe cable 76 may be adjusted or “tuned” for use with the transducer 72 by matching the impedance of the probe 52 to the transducer 72. In certain embodiments, the probe cable 76 may be approximately 1 to 20 meters long. Part (e.g., an end) of the probe cable 76 may be integrally molded with the probe 52. The transducer 72 is further coupled to data acquisition circuitry 74, which is also powered by the power supply 74. As each turbine blade 30 passes the probe tip 56 of the probe 52, the return signal provided by the probe 52 transmits a peak or “blip” in the return signal. The data acquisition circuitry 78 monitors the return signal received by the transducer 72 and assigns a time stamp to each peak or “blip” transmitted in the return signal. In this manner, an interval of elapsed time between the passing of the turbine blades 30 may be calculated within the turbomachine monitoring system 20. The interval of elapsed time between passes of the turbine blade 30 may remain generally constant in the absence of turbine blade 30 deflection, cracking, and the like. However, a deviation in the interval of elapsed time between passes of the turbine blade 30 may be indicative of turbine blade 30 deflection, cracking, or other turbine blade 30 degradation. In this manner, the health of the turbine blades 30 may be monitored through the turbomachine probe assembly 26 of the turbomachine monitoring system 20.

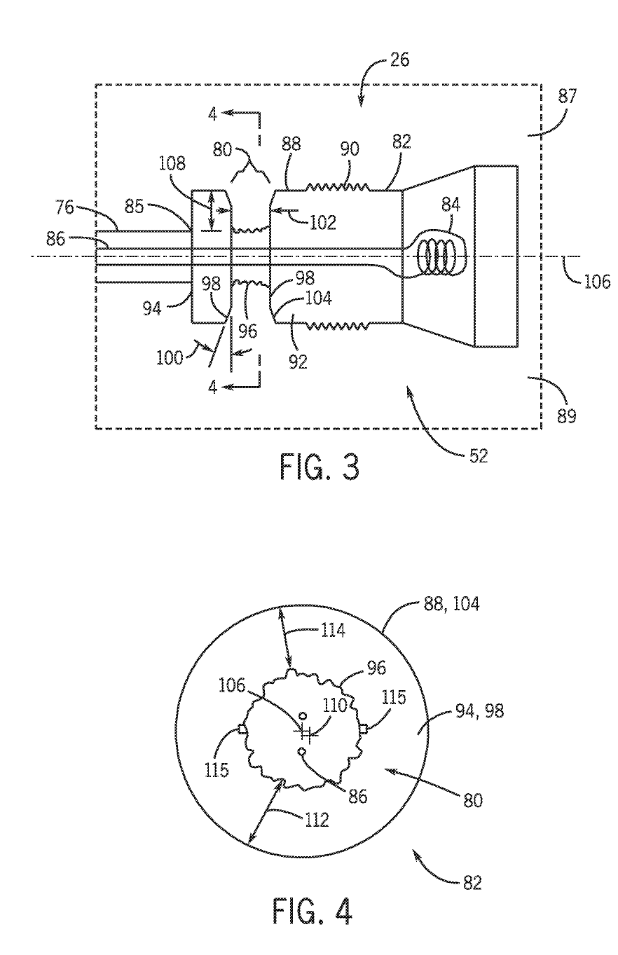

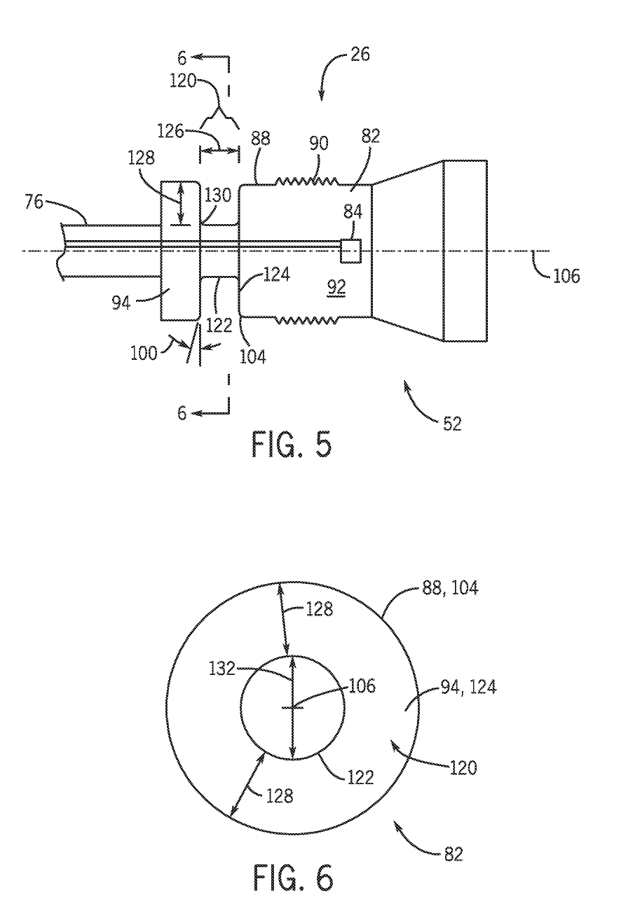

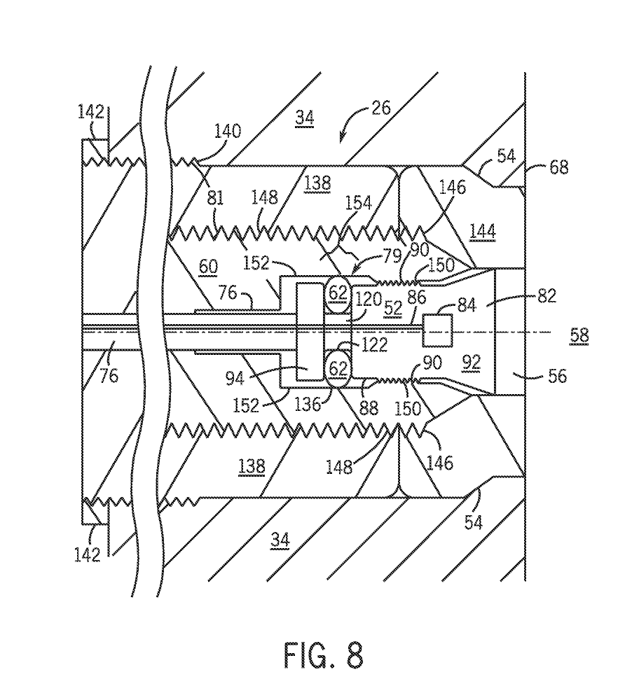

As discussed above, the turbomachine probe assembly 26 may be inserted in the aperture 54 through the turbine casing 34. The aperture 54 provides space for the turbomachine probe assembly 26 to sense conditions within the interior 58 and may inadvertently create a leakage path for fluids (e.g., combustion gases, compressed air) to escape the interior 58 unless the turbomachine probe assembly 26 forms a seal. The gasket 62 between the probe 52 and fitting 60 may seal fluids within the interior 58 and seal the probe circuitry from the fluids within the interior 58. This coupling between the probe 52 and the fitting 60 may be a first seal 79. The fitting 60 may be coupled (e.g., threaded, brazed, welded) within the aperture 54 to retain the fluids within the interior 58 and block leakage between the fitting 60 and aperture 54. This coupling between the fitting 60 and the aperture 54 may be a second seal 81. As discussed below with FIG. 8, in some embodiments the fitting 60 may be coupled to a sheath 138 mounted in the aperture 54. The quality of the first seal 79 depends at least in part on the surface finish of the probe 52 at the interface (e.g., groove 80, 120) with the gasket 62 as discussed below with FIGS. 3-8. Decreased roughness of the probe 52 at a machined surface may increase the quality of the first seal 79. The probe 52 may be conditioned (e.g., machined) as shown in FIGS. 5-8 to decrease the roughness of the molded groove 80 by forming the machined groove 120 to increase the quality of the first seal 79.

FIG. 3 illustrates an embodiment of a molded probe body 82 integrally molded about sensing circuitry 84. The molded probe body 82 may be molded about an end 85 of the probe cable 76 with a first negative mold 87 and a second negative mold 89. In some embodiments, the first and second negative molds 87, 89 may each have half of a negative shape of the molded probe body 82. The molded probe body 82 may be formed from a non-metallic material, such as carbon fiber, polyphenyline sulfide, fiberglass, resin, composite, polyether ether ketone (PEEK), or other plastics. The non-metallic material may be inserted into the first and second negative molds 87, 89 to form the molded probe body 82. Upon forming the molded probe body 82, the first and second negative molds 87, 89 may be removed. The term integrally molded as used herein indicates that the sensing circuitry 84 is integral with the molded probe body 82 as a single component, that is, the probe 52. The molded probe body 82 substantially surrounds and is substantially continuously fixed to the sensing circuitry 84 on all sides. The probe cable 76 has one or more wires 86 to electrically couple the sensing circuitry 84 with the turbomachine monitoring system 20 (FIG. 2). The sensing circuitry 84 may be an eddy current sensor (e.g., inductive coil), thermocouple, thermistor, microwave proximity sensor, emissions sensor, flame sensor, combustion dynamics sensor, pressure sensor, or flow rate sensor, or any combination thereof.

The molded probe body 82 has an outer surface 88 with a first surface finish attributable to the molding process. The molded probe body 82 may be formed by an injection molding or other molding process such as overmolding. The molding process may integrally form the molded probe body 82 within tolerances of the first and second negative molds 87, 89. The mold body 82 may have features on the outer surface 88 such as one or more molded grooves 80 and threads 90 configured to couple with the fitting 60. As illustrated in FIG. 3, a molded groove 80 separates the main body 92 from the base 94 of the molded probe body 82. The molded groove 80 may be configured to receive the gasket 62 (e.g., O-ring seal) to form the first seal 79 between the molded groove 80 and the fitting 60. As discussed above, the quality of the first seal 79 depends at least in part on the surface finish of the molded groove 80.

The first surface finish of the outer surface 88 and molded groove 80 depend at least in part on the molding process, the molded material, and the surface finish of the first and second negative molds 87, 89. When the molded probe body 82 is formed, a groove base 96 and groove sides 98 may have substantially the same surface finish as the first surface finish of the outer surface 88. As shown in FIG. 3, the wavy groove base 96 indicates that the first surface finish has a relatively high roughness value that negatively affects the quality of the first seal 79. For example, injection molding may cause the roughness of the first surface finish to be greater than approximately 3.2 μm (125 μ-in) or 6 μm (250 μ-in). In some embodiments, the injection molding may cause the roughness of the first surface finish to be between approximately 3.2 μm to 12.5 μm (500 μ-in), or any subrange therein. This relatively high roughness value may permit fluids in the interior to leak between the gasket 62 and the groove base 96 of the molded probe body 82, particularly fluids at high pressures. In some embodiments, extra mold material (e.g., flash, parting line) from the molding process may remain on a portion of the outer surface 88 and molded groove 80 to negatively affect the quality of the first seal 79. For example, extra mold material may remain on the molded probe body 82 where the first and second negative molds 87, 89 interfaced (e.g., along the first axis 106).

Due to the nature of the molding process, the sides 98 of the molded groove 80 may have a draft angle 100 (e.g., 1° to 10°) so that the molded probe body 82 may be readily removed from the first and second negative molds 87, 89. As a result, the groove width 102 at the groove base 96 may be less than the groove width 102 at the groove edge 104. The molded probe body 82 may be molded along the first axis 106. In some embodiments, the first and second negative molds 87, 89 are configured to form approximately half of the molded probe body 82 on opposing sides of the first axis 106. In some embodiments, the outer surface 88 may be configured to be rotationally symmetric about the first axis 106. However, imperfections in the mold and extra mold material may result in a varied groove depth 108 about the circumference of the molded groove 80 and/or cause the molded groove 80 to be misaligned with the axis 106. FIG. 4 illustrates a cross-sectional end view of the molded probe body 82 at the molded groove 80 taken within line 4-4. The illustrated groove base 96 has a relatively high roughness as shown by the wavy curve. In an embodiment, the molded groove 80 may be centered about a second axis 110 rather than the first axis 106. The groove depth may differ at points about the molded groove 100 as indicated by arrows 112 and 114. In some embodiments, the mold process may leave extra material 115 (e.g., flash, parting line) from the interface between the first and second negative molds 87, 89. This extra material 115 may affect the surface finish of the molded groove 80 and reduce the effectiveness of a seal. One or more of the surface finish, the axis of the molded groove 80, the symmetry of the molded groove 80, the draft angle 100, and groove depth 108 may affect the quality of the first seal 79.

FIGS. 5 and 6 illustrate cross-sectional side and end views of the turbomachine probe assembly 26 of FIGS. 3 and 4, illustrating a machined groove 120 formed after integrally molding the probe body 82 about the sensing circuitry 84. In some embodiments, the outer surface 88 except for the machined groove 120 may be the same between the molded probe bodies 82 of FIGS. 3 and 5. The machined groove 120 may be formed by machining the molded groove 80 to remove some of the molded material (e.g., flash, parting line) from one or more of the main body 92, the base 94, the groove base 96, and the groove sides 98. In some embodiments, the molded probe body 82 may not have a molded groove 80 and the machined groove 120 may be formed in a portion of the main body 92. Machining may include any manual or automated cutting, drilling, turning, or milling operation, or combinations thereof. The machined groove 120 may be formed by fixing the molded probe body 82 and rotating a cutting tool about axis 106, fixing the cutting tool and rotating the molded probe body 82 about axis 106, or counter-rotating both the molded probe body 82 and the cutting tool about axis 106.

In some embodiments, the machined groove 120 has a second surface finish that is less than or equal to the roughness value of the first surface finish as indicated by the smooth line of a machined groove base 122 shown in FIG. 5. The second surface finish may be smoother than the first surface finish of the molded groove 80. The second surface finish affects the quality of the seal between the gasket 62 and the machined groove base 122. The molded groove 80 may be machined to transform the relatively rough first surface finish of the groove base 96 (FIG. 3) to the relatively smooth second surface finish of the machined groove base 122 (FIG. 5). In some embodiments, the remainder of the outer surface 88 may not be machined and may retain the first surface finish from the molding process. For example, the roughness of the second surface finish may be less than approximately 0.8 μm (32 μ-in), 1.6 μm (63 μ-in), or 3.2 μm (125 μ-in). In some embodiments, the roughness of the second surface finish may be between approximately 0.1 μm (4 μ-in) to 1.6 μm (63 μ-in), approximately 0.2 μm (8 μ-in) to 0.8 μm (32 μ-in), or any subrange therein. A surface finish has a roughness component and a direction component. Ridges of extra material (e.g., flash, parting line) or grooves and voids along the machined groove base 122 that are transverse (e.g., substantially along the first axis 106) to the gasket 62 may affect the seal quality more than ridges and grooves that are substantially parallel with the gasket 62. For example, a machined groove base 122 having grooves and ridges transverse to the gasket 62 with a roughness of approximately 0.4 μm (16 μ-in) may provide substantially the same quality seal as a machined groove base 122 having grooves and ridges substantially parallel to the gasket 62 with a surface roughness of approximately 0.8 μm (32 μ-in) or more. In this manner, the quality of the first seal 79 between the machined groove base 122 and the gasket 62 may be based at least in part on the direction of the machining (e.g., cutting tool rotation about the first axis 106), the type of machining, and the roughness of the second surface finish.

Presently contemplated embodiments of the machined groove 120 are configured to satisfy design specifications for the gasket 62 (e.g., O-ring seal) that is to be received in the machined groove 120. For example, the machined groove 120 may be machined to form a machined groove base 122 and/or machined groove sides 124. The machined groove 120 may have a machined width 126, a machined depth 128, and the machined groove 120 may be disposed transverse to the axis 106 of the probe body 82. In some embodiments, the machined groove 120 may have rounded edges 130. The draft angle 100 of the machined groove 120 may be different than the draft angle 100 of the molded groove 80. For example, the draft angle 100 of the machined groove 120 may range from approximately 0° to 5°.

FIG. 6 illustrates a cross-sectional end view of the molded probe body 82 of FIG. 5 at the machined groove 120 taken within line 6-6. The illustrated machined groove base 122 has a relatively low roughness as shown by the smooth circle. In an embodiment, the machined groove 120 may be centered about the first axis 106 of the molded probe body 82. The machined depth 128 may be substantially equal along the entire machined groove 120. In this way, the machined groove 120 may be symmetrical about the first axis 106 and have a machined groove diameter 132. The machined groove base 122 (e.g., machined surface) may have a substantially uniform second surface finish that is less than or equal to the roughness value of the first surface finish of the outer surface 88. In some embodiments, the second surface finish of the machined groove base 122 and/or machined groove sides 124 may be between approximately 0.4 μm (16 μ-in) to 0.8 μm (32 μ-in), whereas the first surface finish is between approximately 3.2 μm (125 μ-in) to 6.3 μm (250 μ-in). As discussed above, factors that may affect the quality of the first seal 79 include one or more of the second surface finish, the alignment of the axis of the machined groove 120, the symmetry of the machined groove 120, the draft angle 100, and machined depth 128. The machined groove 120 may be machined to adjust one or more of these factors to increase the quality of the first seal 79.

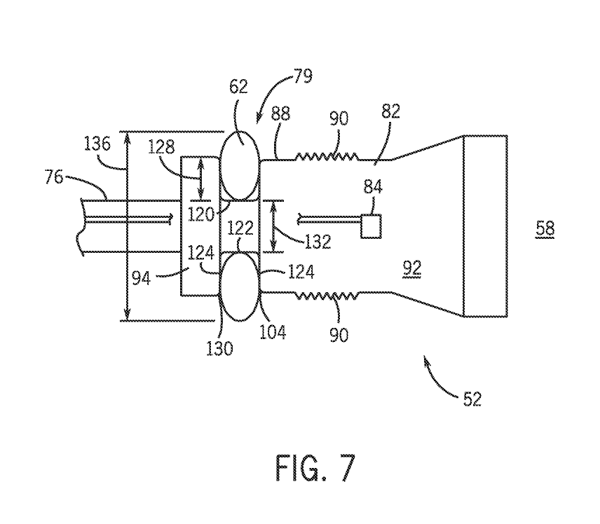

FIG. 7 illustrates a cross-sectional side view of an embodiment of the turbomachine probe assembly 26 of FIGS. 5 and 6 with the machined groove 120, further illustrating a gasket 62 disposed in the machined groove 120 of the molded probe body 82. The gasket 62 may include an O-ring, washer, or other seal. The gasket 62 may interface with the machined groove 120 at the machined groove base 122. In some embodiments, the gasket 62 may have an inner diameter that is less than or equal to the machined groove diameter 132. In some embodiments, the gasket 62 (e.g., O-ring seal) may be resilient and elastically deform to form the first seal 79. The gasket 62 may be made of a resilient material such as nitrile, rubber, silicone, plastic, and so forth. In some embodiments, the gasket 62 may interface with at least one groove side 96 or machined groove side 124. The interface between the gasket 62 and machined groove base 122 form the first seal 79 to retain combustion gases in the interior 58 of the turbine section 18 and seal the sensing circuitry 84 of the probe 52 from the fluids within the interior 58. In some embodiments, the gasket 62 may have an outer edge 136 that extends beyond the groove edge 104 and/or threads 90 when inserted in the machined groove 120.

FIG. 8 illustrates a cross-sectional side view of an embodiment of the turbomachine probe assembly 26 of FIGS. 6 and 7 disposed within the aperture 54 of the turbine casing 34. The turbomachine probe assembly 26 includes the probe 52 disposed within a fitting 60 (e.g., annular fitting), which may be made of a metal, such as stainless steel. The fitting 60 may be directly coupled to the turbine casing 34 or disposed within a sheath 138 (e.g., annular sheath) that is disposed within the aperture 54 formed in the turbine casing 34. More specifically, the illustrated sheath 138 is coupled to the turbine casing 34 by a threaded connection 140 (e.g., male threads of the sheath 138 and female threads of the aperture 54). A jam nut 142 may be disposed about the sheath 138 and adjacent to the turbine casing 34 to secure the turbomachine probe assembly 26 within the aperture 54. Other embodiments of the turbomachine probe assembly 26 may include welded, brazed, or bolted connections of the fitting 60 or sheath 138 to the turbine casing 34.

In some embodiments, a shroud 144 (e.g., annular shroud) may be disposed about the probe tip 56 of the probe 52. More specifically, the illustrated shroud 144 is at least partially secured to the fitting 60 by a threaded connection 146 (e.g., male threads of the fitting 60 and/or probe tip 56, and female threads of the shroud 144). For example, the shroud 144 may be threaded over the fitting 60 and held in place with a thread locking material, epoxy, or other adhesive. In certain embodiments, the shroud 144 may be formed from a non-metallic material, such as a ceramic, composite, or plastic. For example, the shroud 144 may be formed from a carbon fiber, a composite material, polyphenyline sulfide, fiberglass, polyether ether ketone (PEEK), or other plastics. As shown, the shroud 144 abuts the sheath 138 and extends from the sheath 138 approximately to the inner wall 68 of the casing 34. In this manner, the inner wall 68 of the turbine casing 34, the probe tip 56, and the shroud 144 are approximately flush (e.g., no remaining recesses into the wall 64), thereby reducing flow disturbances within the turbine section 18.

The fitting 60 may be mounted within the aperture 54 to locate the probe 52 approximately flush with the inner wall 68. In some embodiments, the fitting 60 may be coupled to the sheath 138 or turbine casing 34 by an external threaded connection 148 (e.g., male threads of the fitting 60 and female threads of the sheath 138). In certain embodiments, an adhesive, sealant, thread locking material, or other surface treatment may be disposed at the threaded connection 140 and/or external threaded connection 148 to secure the threaded connections 140, 148 against at least vibration and shock. The threaded connection 140 and external threaded connection 148 may form the second seal 81 to retain the fluids (e.g., combustion gases) in the interior 58 of the turbine casing 34 and isolate the interior 58 from the external environment outside the turbine casing 34.

The fitting 60 may be disposed about the probe 52 and coupled to the molded probe body 82. An internal threaded connection 150 (e.g., male threads 90 of the molded probe body 82 and female threads of the fitting 60, or female threads of the molded probe body 82 and male threads of the fitting 60) may couple the fitting 60 to the probe 52. The internal threaded connections 150 may be held in place with a thread locking material, epoxy, or other adhesive. The threads 90 of the molded probe body 82 may interface with mating threads on an internal surface 152 of the fitting 60. A region 154 of the internal surface 152 may interface with the gasket 62 with the machined groove 120 to form the first seal 79. In some embodiments, the fitting 60 may compress the gasket 62 to form part of the first seal 79. The region 154 of the internal surface 152 has a third surface finish that affects the quality of the first seal 79. In some embodiments, the third surface finish may be approximately the same as the second surface finish. For example, the third surface finish of the internal surface 152 may have a roughness less than approximately 0.8 μm (32 μ-in), 1.6 μm (63 μ-in), or 3.2 μm (125 μ-in). In other embodiments, the third surface finish may have a roughness between approximately 0.8 μm (32 μ-in) to 6.3 μm (250 μ-in), approximately 1.6 μm (63 μ-in) to 3.2 μm (125 μ-in), or any subrange therein.

As discussed above, the first seal 79 may retain fluids (e.g., combustion gases) in the interior 58 of the turbine casing 34 and seal the sensing circuitry 84 and monitor unit 22 (FIG. 2) from the fluids. The first seal 79 may also isolate the interior 58 from the external environment outside the turbine casing 34. The gasket 62 inserted in the machined groove 120 is configured to interface with both the machined groove base 122 and the region 154 of the internal surface 152 to form the first seal 79. The second and third surface finishes of the machined groove base 122 and the region 154 enable the first seal 79 to seal at increased fluid pressures within the interior 58 of the turbine casing 34. For example, the first seal 79 may be configured to seal up to approximately 0.69 MPa (100 psi), 3.45 MPa (500 psi), 6.89 MPa (1000 psi), 13.79 MPa (2000 psi), or 15.51 MPa (2250 psi). In this way, the first seal 79 may be configured to reduce or substantially eliminate fluid leakage around the gasket 62.

Presently contemplated embodiments include a method of producing the turbomachine probe assembly 26. The sensing circuitry 84 may be disposed in a mold, which receives a mold material around the circuitry 84 to integrally form the molded probe body 82 of the probe 52 about the circuitry 84. In some embodiments, the molded probe body 82 may be integrally molded about a cable 76 coupled with the sensing circuitry 84. The integrally molded probe body 82 may be formed of a non-metallic material, such as carbon fiber, polyphenyline sulfide, fiberglass, resin, composite, polyether ether ketone (PEEK), or other plastics. The molded probe body 82 may have an outer surface 88 with a first surface finish dependent upon the mold. The molded probe body 82 may also have a molded groove 80 formed in the molded probe body 82 having the first surface finish. The molded groove 80 may be machined to form a machined groove 120 having a second surface finish with a roughness value less than or equal to that of the first surface finish. The machined groove 120 may be formed by fixing the molded probe body 82 and rotating a cutting tool about axis 106, fixing the cutting tool and rotating the molded probe body 82 about axis 106, or counter-rotating both the molded probe body 82 and the cutting tool about axis 106. The machined groove 120 may be cleaned before a gasket 62 is inserted in the machined groove 120. Cleaning may remove cuttings from the machining process. The probe 52 and gasket 62 may be positioned within a fitting 60. Positioning may include coupling by a threaded connection. Positioning the fitting 60 about the probe 52 and gasket 62 may seal the machined groove 120 and fitting 60 with the gasket 62, forming the first seal 79. The probe 52 may be configured to be coupled with the fitting 60 to mount the probe 52 with the sensing circuitry 84 near a turbomachine to be monitored. The fitting 60 may be directly mounted in the turbomachine (e.g., turbine casing 34) or coupled to a sheath 138 that may be directly mounted in the turbomachine. In some embodiments, a shroud 144 may be coupled to the probe 52 and/or the fitting 60. The turbomachine probe assembly 26 may be treated by an epoxy, sealant, or adhesive to retain the components of the turbomachine probe assembly 26 together. The turbomachine probe assembly 26, including the probe 52, the gasket 62, and the fitting 62 may be configured to form the first seal 79 to withstand pressures from approximately 0.69 MPa (100 psi) to 15.51 MPa (2250 psi). The turbomachine probe assembly 26 may be tested to determine the operating pressure range of the first seal 79.

Technical effects of embodiments of the invention include a machined groove of a molded probe body that is configured to receive a gasket that may seal to pressures up to approximately 0.69 MPa (100 psi) or approximately 15.51 MPa (2250 psi). The molded probe body may be integrally formed about sensing circuitry and a cable electrically coupled to the sensing circuitry. This integrally formed molded probe body may reduce the time and manufacturing costs associated with manufacturing the probe and turbomachine probe assembly. For example, a plurality of molded probe bodies may be molded simultaneously compared to forming (e.g., machining) probe bodies individually. The molded probe body and molded groove integrally formed with the molded probe body may have a first surface finish dependent upon the molding process. The surface finish of the molded groove, particularly the roughness value, affects the quality of a seal formed between a gasket and the molded groove. Machining the molded groove to form a machined groove with a decreased roughness value may increase the quality of the seal. In some embodiments, only the molded groove is machined to a machined surface, whereas the remainder of the molded probe body is not machined and retains the first surface finish. Thus, forming the machined groove in the molded probe body may increase the quality of the seal and take advantage of the reduced time and manufacturing costs associated with the molding process.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A system, comprising:
a probe assembly, comprising:
sensing circuitry configured to sense at least one parameter relating to a rotating machine;
a cable coupled to the sensing circuitry;
a molded probe body that is integrally molded about the cable and the sensing circuitry; and
a machined groove disposed on the molded probe body, wherein the machined groove comprises a machined surface.

2. The system of claim 1, wherein the probe assembly comprises a proximity probe.

3. The system of claim 2, wherein the proximity probe comprises an eddy current probe.

4. The system of claim 1, wherein the probe assembly comprises a temperature probe, a pressure probe, a combustion dynamics probe, a vibration probe, an eddy current probe, a clearance probe, a speed probe, a flow rate probe, or any combination thereof

5. The system of claim 1, comprising a probe assembly having a gasket disposed in the machined groove of the probe assembly.

6. The system of claim 5, wherein the probe assembly comprises a fitting disposed about the probe assembly, wherein the gasket seals the machined groove with the fitting.

7. The system of claim 1, wherein the machined surface has a second surface finish that is smoother than a first surface finish of an exterior of the molded probe body.

8. The system of claim 7, wherein a first roughness of the first surface finish is greater than approximately 3.2 μm, and second roughness of the second surface finish is approximately 0.8 μm or less.

9. The system of claim 1, wherein the molded probe body comprises a carbon fiber, polyphenyline sulfide, fiberglass, resin, composite, or polyether ether ketone, or combinations thereof.

10. The system of claim 1, comprising a turbomachine having the probe assembly.

11. The system of claim 10, wherein the turbomachine comprises a turbine engine.

12. The system of claim 1, comprising a turbomachine monitoring system having a monitoring unit coupled to the probe assembly.

13. A system, comprising:
a proximity probe, comprising:
sensing circuitry configured to sense at least one parameter relating to a turbomachine blade;
a molded probe body that is integrally molded about the sensing circuitry, wherein the molded probe body has an exterior with a first surface finish; and
a machined groove disposed on the molded probe body, wherein the machined groove comprises a machined surface with a second surface finish that is smoother than the first surface finish.

14. The system of claim 13, wherein the proximity probe comprises an eddy current probe.

15. The system of claim 13, comprising a turbomachine having the proximity probe, or a turbomachine monitoring system having a monitoring unit coupled to the probe, or a combination thereof.

16. The system of claim 13, comprising a probe assembly having a cable coupled to the sensing circuitry of the proximity probe and a gasket disposed in the machined groove of the probe, wherein the molded probe body is integrally molded about the cable.

17. A method, comprising:
machining a groove in a probe body of a proximity probe after the probe body is integrally molded about sensing circuitry configured to sense at least one parameter relating to a turbomachine, wherein machining the groove creates a machined surface in the groove configured to support a gasket.

18. The method of claim 17, comprising integrally molding the probe body about the sensing circuitry and a cable coupled to the sensing circuitry.

19. The method of claim 17, comprising inserting the gasket in the groove, and mounting the proximity probe to a turbomachine.

20. The method of claim 17, comprising removing cuttings from the groove.
